(19) United States
(12) Patent Application Publication
(10) Pub. No.: US 2024/0418276 A1
(43) Pub. Date: Dec. 19, 2024

(54) VALVE FOR SEMICONDUCTOR EQUIPMENT

(71) Applicant: LAM RESEARCH CORPORATION, Fremont, CA (US)

(72) Inventors: John Michael WILTSE, Lake Oswego, OR (US); Bin LUO, Beaverton, OR (US); Brian RATLIFF, Hillsboro, OR (US)

(21) Appl. No.: 18/701,458

(22) PCT Filed: Oct. 24, 2022
(86) PCT No.: PCT/US2022/047542

§ 371 Date: Apr. 15, 2024

Related U.S. Application Data
(60) Provisional application No. 63/273,701, filed on Oct. 29, 2021.

(51) Int. Cl. F16K 11/10; F16K 13/00; F16M 13/02

(52) U.S. Cl. CPC F16K 11/105; F16K 13/00; F16M 13/02

(57) ABSTRACT

A valve comprising a valve body including an inlet, an outlet and a mounting surface. A first valve actuator is connected to the valve body. A plurality of mounting holes are formed in the mounting surface. The plurality of mounting holes are asymmetric relative to the mounting surface.

### CROSS-REFERENCE TO RELATED APPLICATIONS

This application claims the benefit of U.S. Provisional Application No. 63/273,701, filed on Oct. 29, 2021. The entire disclosure of the above application is incorporated herein by reference.

### FIELD

The present disclosure relates to valves for substrate processing systems, and more particularly valves with mistake proof features to prevent installation errors.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to perform deposition, etching and/or other treatment of substrates such as semiconductor wafers. A substrate may be arranged on a pedestal in a processing chamber. During deposition, a deposition gas mixture including one or more precursors is supplied by a gas delivery system to the processing chamber. During etching, an etch gas mixture is supplied to the processing chamber. In some applications, plasma may be struck in the processing chamber to promote chemical reactions.

The gas delivery system includes gas lines, process gas valves, mass flow controllers and other devices to control the flow of gases to a processing chamber of the substrate processing system. The process gas valves typically have two ports (in the case of two way valves) or three ports (in the case of three way valves). Two way valves need to be oriented correctly for the valve to provide a predetermined conductance (Cv). In other words, the process gas valve will operate differently than specified when oriented incorrectly.

The orientation of three way valves is even more important. When a three way valve is reversed, process or clean gasses will not flow to a correct path. This mistake can cause process gasses to flow to the wrong location or incompatible gasses mixing in the gas lines (resulting in “dusting” of the gas lines).

While the orientation of the process valves is important, the process gas valves are completely symmetric (fittings, mounting features, etc.) making them difficult to orient correctly. Typically, the process valves include a flow diagram or flow arrow to define the orientation of the process valve. Manufacturing technicians and field personnel rely on detailed work instructions to install the valves correctly. In the case of three way valves, this is particularly challenging since the flow diagrams on these valves require considerable skill to interpret.

One possible solution to mistake proof valves includes changing the connectors on the valves. Current valves typically have a female connection on each port. The valves could be mistake proofed by changing one of these connections to a male connection. However, this approach significantly affects on the rest of the design of the gas delivery system. Gas lines would need to be changed to accommodate the new connector setup. Filters and other valves on a manifold stick would also need to change. Since each valve may be used in more than one application, this approach may necessitate releasing more than one version of a non-symmetric valve, i.e. one version may have a male connector on one of the inlets, and another may have a male connector on one of the outlets. These valves would also not be backwards compatible into non-mistake proof legacy applications.

### SUMMARY

A valve comprising a valve body including an inlet, an outlet and a mounting surface. A first valve actuator is connected to the valve body. A plurality of mounting holes are formed in the mounting surface. The plurality of mounting holes are asymmetric relative to the mounting surface.

In other features, when the valve body is arranged in a first mounting orientation, the plurality of mounting holes orient the valve body in a first position relative to mounting holes in a mounting bracket. When the valve body is arranged in a second mounting orientation that is rotated 180° degrees relative to the first position, the plurality of mounting holes cause the valve body to have a second position, relative to the mounting holes in the mounting bracket, that is displaced by a predetermined distance greater than zero relative to the first position.

In other features, the valve is a three way valve, the valve body further includes a second inlet and the valve further comprises a second valve actuator.

In other features, the valve is a three way valve, the valve body further includes a second outlet, and the valve further comprises a second valve actuator.

In other features, the valve body includes a horizontal center line and a vertical center line. The plurality of mounting holes in the mounting surface includes two holes that are arranged on one side of the horizontal center line.

In other features, the valve body includes a horizontal center line and a vertical center line. The plurality of mounting holes in the mounting surface includes two holes that are arranged on one side of the vertical center line. The valve is a two way valve having a first conductance in a first flow direction and a second conductance in a second flow direction.

In other features, the plurality of mounting holes comprises four mounting holes that are symmetric relative to the mounting surface. Two of the four mounting holes are blocked. The two of the four mounting holes are blocked by a set screw.

A valve assembly comprises the valve. A mounting bracket includes a first set of mounting holes configured to align with the plurality of mounting holes on the mounting surface of the valve body. The mounting bracket does not include unused mounting holes in contact with the mounting surface of the valve body.

In other features, the mounting bracket includes a second set of mounting holes configured to align with the plurality of mounting holes on the mounting surface of the valve body of a second one of the valve. The second one of the valve is arranged on the mounting bracket in an orientation that is rotated 180 degrees relative to the valve.

A valve comprises a valve body including an inlet, an outlet and a mounting surface. A first valve actuator connected to the valve body. A plurality of mounting holes are formed in the mounting surface. A first hole is arranged in an asymmetric position on the mounting surface.

In other features, the valve is a three way valve, the valve body further includes a second inlet, and the valve further comprises a second valve actuator.

In other features, the valve is a three way valve, the valve body further includes a second outlet, and the valve further comprises a second valve actuator.

In other features, the valve is a two way valve having a first conductance in a first flow direction and a second conductance in a second flow direction. The second conductance is different than the first conductance.

In other features, a pin is arranged in the first hole.

A valve assembly includes the valve and a mounting bracket including a first set of mounting holes configured to align with the plurality of mounting holes on the mounting surface of the valve body and a second hole configured to receive the pin.

A valve assembly includes the valve and a mounting bracket including a first set of mounting holes configured to align with the plurality of mounting holes on the mounting surface of the valve body. A pin is received in the hole in the mounting surface of the valve body.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of an example of mistake proof valves, filters and other gas delivery system components mounted on a mounting bracket according to the present disclosure;

FIGS. 2 and 3 are side views illustrating examples of three way valves;

FIGS. 4 and 5 are bottom views illustrating examples of symmetric mounting holes on a mounting surface of a valve;

FIGS. 6A to 6C are bottom views illustrating examples of valves including asymmetric mounting holes according to the present disclosure;

FIG. 7 is a perspective view of an example of a mounting bracket including asymmetric holes according to the present disclosure;

FIG. 8 is a bottom view of an example of a valve including mounting holes to receive fasteners and an asymmetric hole for receiving a dowel pin according to the present disclosure;

FIG. 9 is a perspective view of an example of a mounting bracket including mounting holes for receiving a fastener and a dowel pin located asymmetrically according to the present disclosure;

FIG. 10 is a bottom view of an example of a valve including mounting holes to receive fasteners and a dowel pin according to the present disclosure; and

FIG. 11 is a perspective view of an example of a mounting bracket including mounting holes to receive fasteners and a mounting hole located asymmetrically to receive a dowel pin according to the present disclosure.

In the drawings, reference numbers may be reused to identify similar and/or identical elements.

### DETAILED DESCRIPTION

The present disclosure describes several different approaches for mistake proofing installation of process valves for a gas delivery system of a substrate processing system. The process valves are typically mounted to and held in position by a mounting bracket. In one approach, the valves according to the present disclosure include mounting features (e.g. threaded holes on a mounting surface of a valve body or a hole or dowel pin) that are asymmetrically positioned. The asymmetry can be seen when the valve is rotated 180 and the mounting holes are in a different position relative to the valve body. As a result, the valve can be used with a mounting bracket with matching holes that are aligned with a correct orientation of the valve to prevent incorrect installation.

For example, conventional valves often include four symmetric mounting holes that are in the same location relative to the valve body when the valve is rotated 180°. The mounting bracket includes four holes that align with the mounting holes of the valve independently of the orientation of the valve body. A similar result can be obtained when using two mounting holes on the valve body in a diagonal position relative to a center of the valve body.

In some examples, the valve according to the present disclosure includes two tapped holes (two on top or bottom, or two on one or the other side of the valve body). The mounting bracket includes two holes (instead of four) arranged in a predetermined location to require one orientation rather than the other orientation. As a result, the valve can only be installed in the one orientation without causing other alignment problems. In other words, other gas delivery system components such as filters, other valves, tubes and connectors, etc. will not have the correct fitment (they will be either too short or long).

In another approach, an asymmetric hole is formed in the mounting surface of the valve body along with the mounting holes that receive fasteners. A dowel pin is arranged on the mounting bracket to provide an orienting feature. In an alternative approach, a dowel pin is added to the mounting surface of the valve body in an asymmetric location (instead of on the mounting bracket). A hole is added to the mounting bracket to receive the dowel pin.

The valves and mounting brackets according to the present disclosure allow the valves to be mistake proofed to improve manufacturability, serviceability, and customer quality. The valves with the mistake-proofing features are backwards compatible. In other words, the valves can be used in pre-existing non-mistake proofed applications. Valves with the mistake proof features can be implemented with minimal additional design changes. Typically only a mounting bracket would need to change. Other ways of mistake proofing valves (for example, male and female connections to force a particular orientation) would require redesign of other system components.

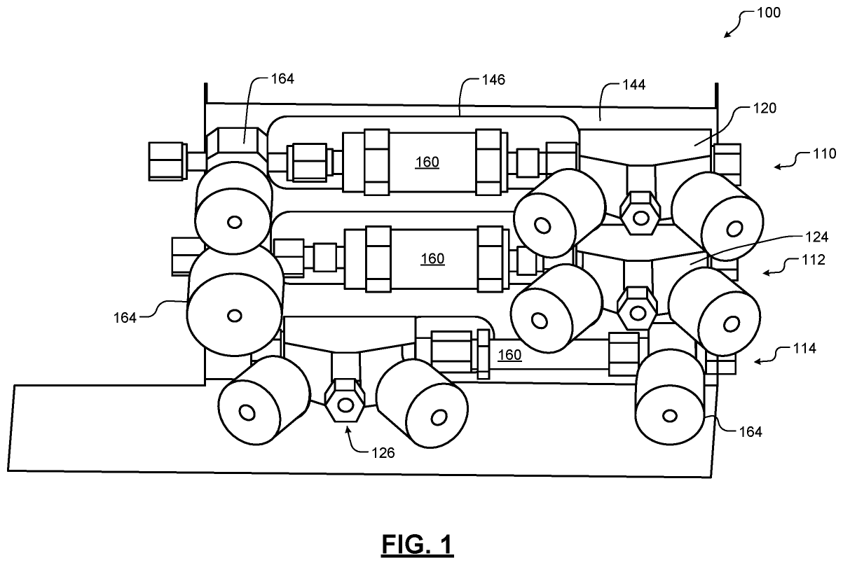

Referring now to FIG. 1, mistake proof valves, filters and other components are shown mounted on a mounting bracket. A valve assembly 100 includes a first gas flow path 110, a second gas flow path 112, and a third gas flow path 114. A first valve 120 is arranged in the first gas flow path 110. A second valve 124 is arranged in the second gas flow path 112. A third valve 126 is arranged in the third gas flow path.

Various additional gas system components are arranged in the first gas flow path 110, the second gas flow path 112, and/or the third gas flow path 114. The various additional components may include filters 160, valves 164, pressure sensors, etc. The first valve 120, the second valve 124 and the third valve 126 are mounted to a mounting bracket 144. The mounting bracket 144 may include one or more access holes 146 and mounting holes (shown below) to allow access to a back side.

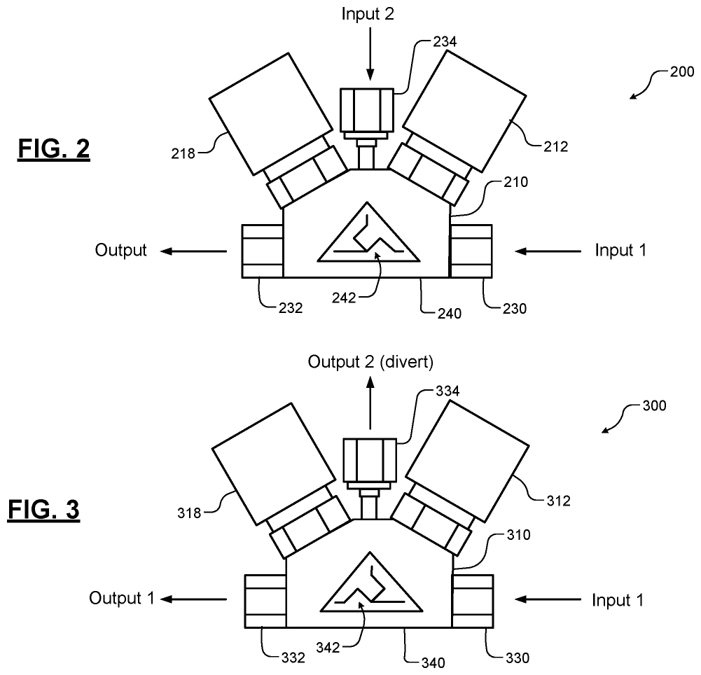

Referring now to FIGS. 2 and 3, three way valves having the same form factor are shown. While the foregoing description relates to three way valves, a similar approach can be used for two way valves (to ensure proper conductance). In FIG. 2, a valve 200 includes a valve body 210 and valve actuators 212 and 218. The valve 200 includes fittings 230, 232 and 234 associated with Input 1, Output and Input 2, respectively. The valve 200 includes a mounting surface 240 located on the valve body 210. In some examples, the valve 200 may include a schematic or other marking identified at 242 to identify the configuration of the valve 200.

In FIG. 3, a valve 300 includes a valve body 310 and valve actuators 312 and 318. The valve 300 includes fittings 330, 332 and 334 associated with Input, Output 1 and Output 2 (or divert), respectively. The valve 300 includes a mounting surface 340 located on the valve body 310. In some examples, the valve 300 may include a schematic or other marking identified at 342 to identify the configuration of the valve 300. As can be seen in FIGS. 2 and 3, the valves 200 and 300 have the same form factor. When installed in the two orientations, the valves 200 and 300 can be attached to the mounting bracket without physical offset in a horizontal direction.

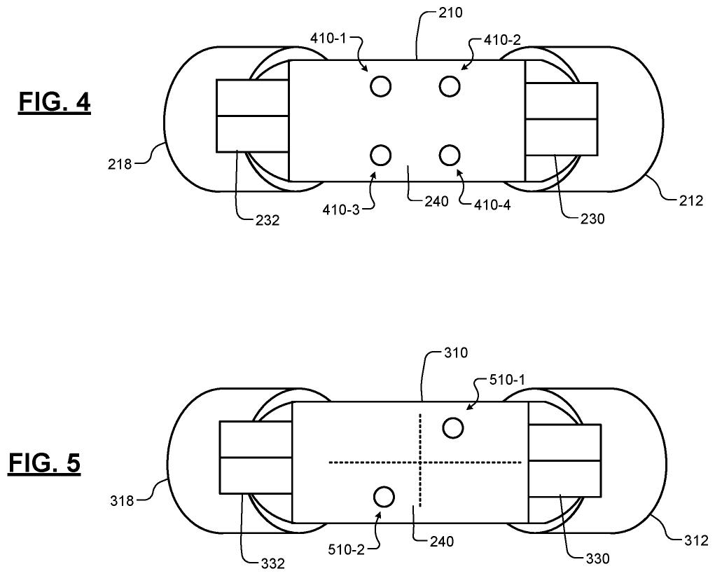

Referring now to FIGS. 4 and 5, examples of symmetric mounting holes on a mounting surface of a valve are shown. In FIG. 4, the mounting surface 240 includes mounting holes 410-1, 410-2, 410-3, and 410-4 that are arranged in a rectangular or square orientation and that are symmetric about a center location of the mounting surface of the valve body. In FIG. 5, the mounting surface 240 includes holes 510-1 and 510-2 having a diagonal arrangement relative to the center of the mounting surface of the valve body. As can be appreciated, the valves 200 and 300 can be attached to the mounting bracket in either direction with either configuration since the mounting holes have the same pattern when rotated 180°.

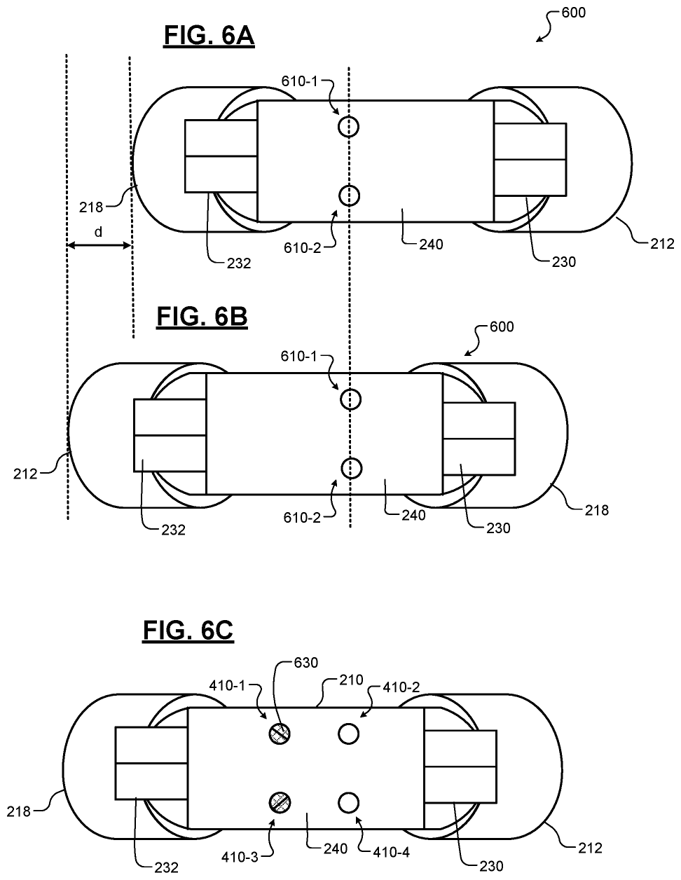

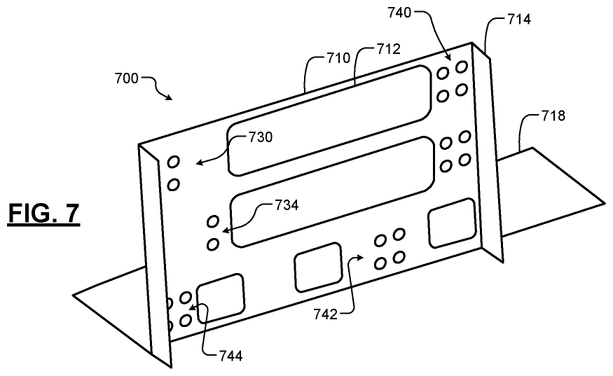

Referring now to FIGS. 6A to 6C, a valve 600 is shown to include asymmetric mounting holes 610-1 and 610-2. The mounting holes 610-1 and 610-2 are asymmetric in that their relative position changes when the valve 600 is rotated 180°. The valve 600 is shown in two positions in FIGS. 6A and 6B (one rotated 180° relative to the other). As can appreciated, when installed in the two orientations, the valve 600 cannot be attached to the mounting bracket without physical offset in a horizontal direction. As shown in FIGS. 6A and 6B, the valve is offset by distance d due to the asymmetric mounting holes.

In FIG. 6C, if the valve 600 starts with symmetric mounting holes (e.g. four mounting holes), two of the four mounting holes can be blocked or filled to achieve a similar effect. For example, set screws 630 can be used to fill two of the four mounting holes as shown. In some examples, the set screws sit flush with or below the surface of the mounting surface. In some examples, the set screws are permanently installed using adhesive, thread locker or other suitable material. Alternately, two of the four mounting holes can be filled with a material such as epoxy or other material to achieve a similar effect. In effect, two of the four mounting holes can no longer be used as mounting holes.

Referring now to FIG. 7, a mounting bracket 700 is shown. In some examples, the mounting bracket 700 includes access holes 712. The mounting bracket 700 may also include flanges 714 and 718 to provide additional mounting surfaces and/or added strength. The mounting bracket 700 includes mounting holes 730 and 734 that are arranged on the mounting bracket 700 for the valve 600 with asymmetric mounting holes. In some examples, the mounting bracket 700 includes other mounting holes that are symmetric such as those shown at 740, 742 and 744 (for components that do not have asymmetric mounting holes).

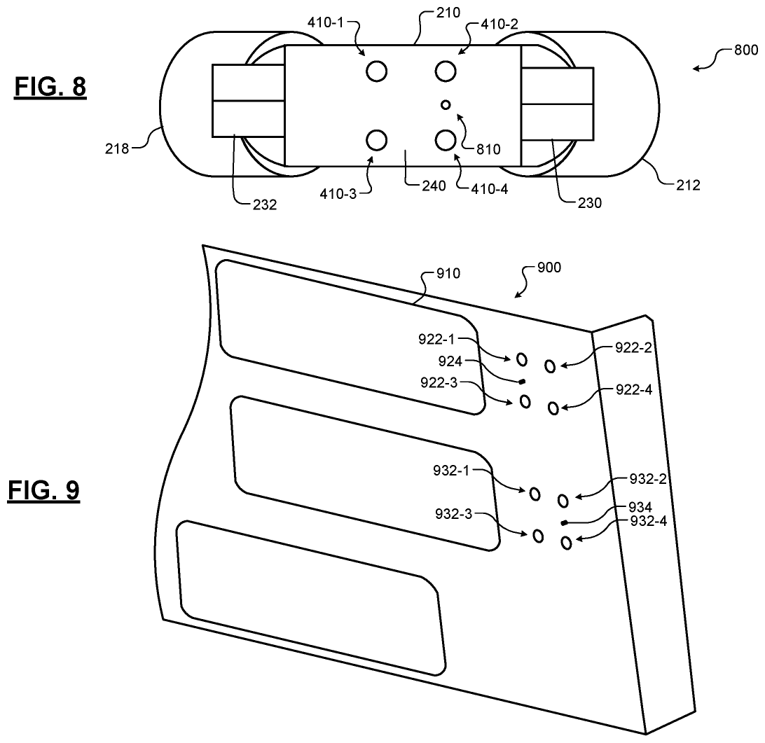

Referring now to FIGS. 8 and 9, another asymmetric arrangement is shown. In this example, a valve 800 includes symmetric mounting holes 410-1, 410-2, 410-3 and 410-4 in the mounting surface 240 to receive fasteners. Another hole 810 is provided in the mounting surface in an asymmetric location to receive a dowel pin. In FIG. 9, a mounting bracket 900 includes first mounting holes 920 for mounting the valve 800 in a first orientation. The first mounting holes 920 include mounting holes 922-1, 922-2, 922-3, and 922-4 aligning with the mounting holes 410-2, 410-1, 410-4 and 410-2, respectively. A pin 924 is received by mounting hole 810.

The mounting bracket 900 includes second mounting holes 930 for mounting another one of the valves 800 in a second orientation. The second mounting holes include mounting holes 932-1, 932-2, 932-3, and 932-4 aligning with the mounting holes 410-1, 410-2, 410-3 and 410-4, respectively. A pin 934 is received by mounting hole 810.

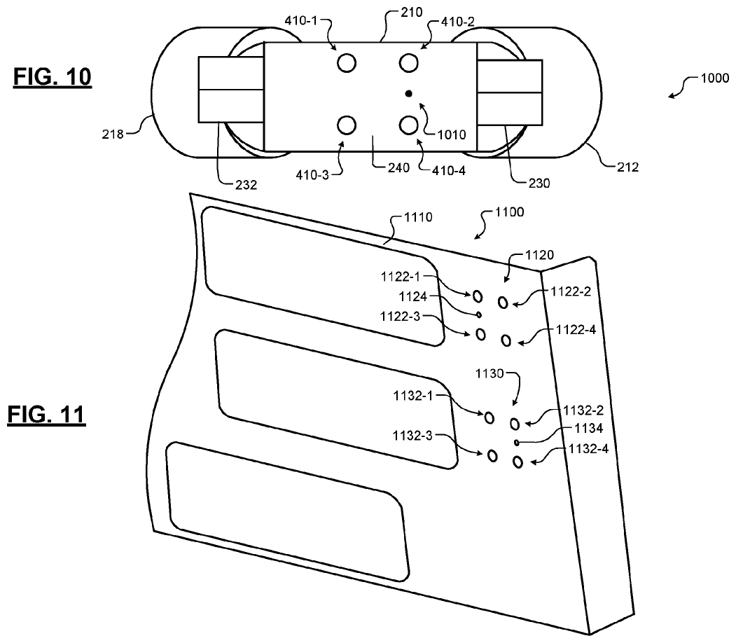

Referring now to FIGS. 10 and 11, another asymmetric arrangement is shown. In this example, a valve 1000 includes symmetric mounting holes 410-1, 410-2, 410-3 and 410-4 in the mounting surface 240 to receive fasteners. A pin 1010 arranged in a mounting hole is provided in the mounting surface 240 in an asymmetric location. In FIG. 11, a mounting bracket 1100 includes first mounting holes 1120 for mounting the valve 1000 in a first orientation. The first mounting holes 1120 include mounting holes 1122-1, 1122-2, 1122-3, and 1122-4 aligning with the mounting holes 410-2, 410-1, 410-4 and 410-2, respectively. The pin 1010 is received by mounting hole 1124.

The mounting bracket 1100 includes second mounting holes 1130 for mounting another one of the valves 1000 in a second orientation. The second mounting holes 1130 include mounting holes 1132-1, 1132-2, 1132-3, and 1132-4 aligning with the mounting holes 410-1, 410-2, 410-3 and 410-4, respectively. The pin 1010 is received by mounting hole 1134.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A valve comprising:
a valve body including an inlet, an outlet and a mounting surface;
a first valve actuator connected to the valve body; and
a plurality of mounting holes formed in the mounting surface,
wherein the plurality of mounting holes are asymmetric relative to the mounting surface.

2. The valve of claim 1, wherein:
when the valve body is arranged in a first mounting orientation, the plurality of mounting holes orient the valve body in a first position relative to mounting holes in a mounting bracket; and
when the valve body is arranged in a second mounting orientation that is rotated 180° degrees relative to the first position, the plurality of mounting holes cause the valve body to have a second position, relative to the mounting holes in the mounting bracket, that is displaced by a predetermined distance greater than zero relative to the first position.

3. The valve of claim 1, wherein:
the valve is a three way valve;
the valve body further includes a second inlet; and
the valve further comprises a second valve actuator.

4. The valve of claim 1, wherein:
the valve is a three way valve;
the valve body further includes a second outlet; and
the valve further comprises a second valve actuator.

5. The valve of claim 1, wherein:
the valve body includes a horizontal center line and a vertical center line; and
the plurality of mounting holes in the mounting surface includes two holes that are arranged on one side of the horizontal center line.

6. The valve of claim 1, wherein:
the valve body includes a horizontal center line and a vertical center line; and
the plurality of mounting holes in the mounting surface includes two holes that are arranged on one side of the vertical center line.

7. The valve of claim 1, wherein the valve is a two way valve having a first conductance in a first flow direction and a second conductance in a second flow direction.

8. The valve of claim 1, wherein:
the plurality of mounting holes comprises four mounting holes that are symmetric relative to the mounting surface; and
two of the four mounting holes are blocked.

9. The valve of claim 8, wherein the two of the four mounting holes are blocked by a set screw.

10. A valve assembly comprising:
the valve of claim 1; and
a mounting bracket including a first set of mounting holes configured to align with the plurality of mounting holes on the mounting surface of the valve body.

11. The valve assembly of claim 10, wherein the mounting bracket does not include unused mounting holes in contact with the mounting surface of the valve body.

12. The valve assembly of claim 10, further comprising a second one of the valve, wherein the mounting bracket includes a second set of mounting holes configured to align with the plurality of mounting holes on the mounting surface of the valve body of the second one of the valve.

13. The valve assembly of claim 12, wherein the second one of the valve is arranged on the mounting bracket in an orientation that is rotated 180 degrees relative to the valve.

14. A valve comprising:
a valve body including an inlet, an outlet and a mounting surface;
a first valve actuator connected to the valve body;
a plurality of mounting holes formed in the mounting surface; and
a first hole arranged in an asymmetric position on the mounting surface.

15. The valve of claim 14, wherein:
the valve is a three way valve;
the valve body further includes a second inlet; and
the valve further comprises a second valve actuator.

16. The valve of claim 14, wherein:
the valve is a three way valve;
the valve body further includes a second outlet; and
the valve further comprises a second valve actuator.

17. The valve of claim 14, wherein the valve is a two way valve having a first conductance in a first flow direction and a second conductance in a second flow direction.

18. The valve of claim 14, further comprising a pin arranged in the first hole.

19. A valve assembly comprising:
the valve of claim 18; and
a mounting bracket including a first set of mounting holes configured to align with the plurality of mounting holes on the mounting surface of the valve body and a second hole configured to receive the pin.

20. A valve assembly comprising:
the valve of claim 14;
a mounting bracket including a first set of mounting holes configured to align with the plurality of mounting holes on the mounting surface of the valve body; and
a pin, wherein the pin is received in the hole in the mounting surface of the valve body.
